(19) United States
(12) Patent Application Publication
(10) Pub. No.: US 2016/0068387 A1
(43) Pub. Date: Mar. 10, 2016

(54) SEMICONDUCTOR CAVITY PACKAGE USING PHOTOSENSITIVE RESIN

(71) Applicant: Texas Instruments Incorporated, Dallas, TX (US)

(72) Inventor: Noboru Nakanishi, Oita-Ken (JP)

(21) Appl. No.: 14/480,658

(22) Filed: Sep. 9, 2014

(51) Int. Cl. B81C 1/00; B81B 7/00

(52) U.S. Cl. CPC B81C 1/00293; B81B 7/0041; B81B 7/0058; B81C 1/0023; B81C 1/00904

(57) ABSTRACT

A packaged device (100) with a semiconductor chip (101) with a MEMS device (102) in the central chip area, wherein the package includes a light-sensitive first (150) and an opaque second (160) polymerized compound. The second compound (160) encapsulates the chip peripheral areas with the terminals (103) and wire bonds (130), and forms a sidewall (160a, diameter 112) around the un-encapsulated central area. The first compound (150) continues from the sidewall inward as a frame (inner diameter 110) around the un-encapsulated central area.

### FIELD

Embodiments of the invention are related in general to the field of semiconductor devices and processes, and more specifically to the structure and fabrication method of cavity packages using photosensitive resin.

### DESCRIPTION OF RELATED ART

The wide variety of products collectively called Micro-Electro-Mechanical devices (MEMS) are small, low weight devices on the micrometer scale, which may have mechanically moving parts and often movable electrical power supplies and controls, or they may have parts sensitive to thermal, acoustic, or optical energy. MEMS have been developed to sense mechanical, thermal, chemical, radiant, magnetic, and biological quantities and inputs, and produce signals as outputs. An example of MEMS includes mechanical sensors, both pressure sensors including microphone membranes, and inertial sensors such as accelerometers coupled with the integrated electronic circuit of the chip. Mechanical sensors react to and measure pressure, force, torque, flow displacement, velocity, acceleration, level, position, tilt, and acoustic wavelength and amplitude.

A Micro-Electro-Mechanical System (MEMS) integrates mechanical elements, sensors, actuators, and electronics on a common substrate. The manufacturing approach of a MEMS aims at using batch fabrication techniques similar to those used for microelectronics devices. MEMS can thus benefit from mass production and minimized material consumption to lower the manufacturing cost, while trying to exploit the well-controlled integrated circuit technology.

Because of the moving and sensitive parts, MEMS have a need for physical and atmospheric protection. Consequently, MEMS are adhesively placed on a rigid substrate, electrically connected to the substrate terminals, and surrounded by a housing or package also adhesively placed on the substrate. The housing forms a cavity around the MEMS with an opening, which may be closed by a lid. The housing and lid, and the adhesive layers, have to shield the MEMS against ambient and electrical disturbances, and against stress. Given the small size and high sensitivity of the MEMS, packages generally have complex structures and assembly flows, and a high cost, even for plastic packages, compared to packages of common semiconductor devices. Examples of MEMS devices preferably housed in a cavity package include optical and electromagnetic wave (e.g., infrared) sensors, acoustic (e.g., ultrasonic) and magnetometric sensors, mechanical and physical (e.g., velocity and pressure) sensors and strain gauges, thermal and atmospheric (e.g., temperature and humidity) sensors, chemical (e.g., gas and glucose) biosensors, and living body (e.g., odor and tactile) sensors.

For quasi-hermetic encapsulations, which prevent the ingress of nano-particles, but not of water and oxygen molecules, a MEMS package can be built step-by-step with plastic materials and photolithographic techniques in a batch process flow. For example, packages for bulk acoustic wave (BAW) filters have been manufactured, with micrometer accuracy, using three deposition steps for plastic or metallic layers and two photolithographic definition steps.

Another example of a quasi-hermetic encapsulation is a cavity for a MEMS device covered by a lid of flat metal or of a polymer compound and glued by an adhesive polymer across the cavity or onto straight metal walls surrounding the MEMS device. When a wall is used, the photolithographic technology for the micrometer-scale package couples the wall thickness to the wall height, requiring an aspect ratio of at least 1 to 2. The lid may have an opening as an ingress of radiation to reach the MEMS on the surface of the chip.

### SUMMARY

Applicant realized that one of the ongoing market trends for semiconductor products is the continuing miniaturization both of footprint and of height of the packaged device. For MEMS devices, this may include an ongoing effort to shrink the cavity, or even to eliminate it while substituting for it a window through the package material. For reasons of controlled manufacturing, the package material is frequently a polymeric compound suitable for transfer molding processes.

Applicant performed an analysis of 5σ tolerances involved in transfer molding processes of cavity packages for MEMS devices. In this molding technology, a plurality of silicon chips with MEMS devices is attached onto a substrate such as a leadframe strip and the assembly is then placed in a steel mold cavity to encapsulate each device in a plastic packaging compound. The flippable top half of the steel mold is designed to have an array of steel protrusions, one protrusion per device of the substrate assembly placed in the bottom half of the mold cavity. When mold is closed by lowering the top half onto the bottom half, the protrusions fill the space over the MEMS and thereby keep the compound away; where the protrusions had been, the package will exhibit a window for the MEMS. The analysis took into account the height tolerances of the chip, the attach compound, and the mold clamp mechanism.

In order to satisfy a 5σ process capability, the analysis pointed to the requirement for an air gap or a soft buffer material of a height between the steel protrusion and the chip surface suitable to compensate for the σ tolerances of the chip height, the attachment layer height, and the mold clamping process. Quantitative numbers resulted in a cushion requirement of a height that conventional release films over the steel mold half are not nearly sufficient to satisfy the requirement. Applicant solved the problem of a suitable buffer when he discovered a polymeric compound as portion of the device package, wherein the compound remains soft during the encapsulation process, can thereafter be hardened, and is furthermore photo-sensitive so that low-cost photomasks can customize compound height and width for MEMS-specific package configurations.

An embodiment of the invention is a package for a semiconductor chip with a MEMS device in the central chip area, wherein the package includes a light-sensitive first and an opaque second polymerized compound. The second compound encapsulates the chip peripheral areas with the terminals and wire bonds, and forms a sidewall around the un-encapsulated central area. The first compound continues from the sidewall as a frame around the un-encapsulated central area.

Another embodiment of the invention is a method for fabricating a packaged MEMS device. A semiconductor wafer has a plurality of chip sites, each site including a central area with a MEMS device and peripheral areas with integrated circuits and terminals. A plastic film of a soft and light-sensitive first polymerizable compound is laminated over the surface of the wafer. A photomask is then laminated over the film, the photomask having patterns defining the outlines and widths for frames around the central area of each chip site. The film is illuminated, developed, and etched, retaining un-etched film portions as frames of soft first compound around the central area of each chip site. Thereafter, the wafer is diced to singulate a plurality of discrete semiconductor chips, each chip including a central area surrounded by a frame of soft first compound and peripheral areas with terminals. A plurality of semiconductor chips is attached on the pads of a rigid substrate strip using adhesive layers, and the chip terminals are wire-bonded to adjacent substrate metal contacts. The strip with the attached chips is placed in a mold having a rigid cover with solid protrusions configured to fill the space over the framed central area of each chip; the mold cover is clamped until a respective protrusion touches the frame of soft first compound surrounding the central area of each chip. The substrate surface, wire connections, and chip peripheries contiguous with the frames are encapsulated using an opaque second polymerizable compound, while each framed central area covered by a protrusion is left un-encapsulated. After raising the temperature to polymerize and harden the first and second compounds, the mold cover is opened to expose the strip of packaged devices with central openings containing MEMS devices, and the substrate strip is sawed to singulate discrete packaged devices.

It is a technical advantage that a certain portion of the MEMS device package can be formed before the complete package is formed, and that this early portion can then act as a tolerance compensator for forming the complete package within 5σ quality standards.

It is another technical advantage that, due to its photosensitivity, the early package portion can be adjusted quickly to any package configuration a special MEMS characteristic may require.

It is another technical advantage that the photosensitive material for the early package portion can be applied to a whole semiconductor wafer, thus allowing cost-saving batch processing.

### BRIEF DESCRIPTION OF THE DRAWINGS

FIG. 1A illustrates a cross section of an exemplary MEMS device in a cavity package, which includes a portion made of light-sensitive resin according to the invention.

FIG. 1B shows a top view of the cavity package shown in FIG. 1A.

FIG. 2 illustrates a cross section of an exemplary MEMS device in another cavity package, which includes a portion made of light-sensitive resin according to the invention.

FIG. 3 depicts a top view of a cavity package for a MEMS device showing detail of the light-sensitive package portion surrounding the central chip area.

FIG. 4A is a cross section of a device positioned in a mold with the top mold cover clamped in order to define the characteristics of a buffer material in the space between top cover and device.

FIG. 4B shows a perspective view of the top mold cover with an exemplary protrusion, which defines the configuration of the cavity package-to-be-molded.

FIG. 4C illustrates a cross section of the top mold cover with a release film.

FIG. 4D shows Table I listing experiential process tolerances and a values contributing to an encapsulation process aiming at 5σ accuracy.

FIG. 5 illustrates the process of laminating a film of a soft light-sensitive first compound on a semiconductor wafer surface.

FIG. 6 shows the processes of aligning a photomask over the film and illuminating the film through the mask.

FIG. 7 depict the process of etching the film and retaining un-etched film portions as frames of soft first compound around the central area of chip sites.

FIG. 8 shows the process of dicing the wafer to singulate discrete chips.

FIG. 9 illustrates the process of attaching chips on pads of a substrate strip using an adhesive layer.

FIG. 10 depicts the process of wire bonding the chip terminals to substrate contacts.

FIG. 11 summarizes the process of encapsulating, while the mold cover with protrusions is clamped, the substrate surface, wire connections and chip peripheries contiguous with the frames in an opaque second compound, leaving un-encapsulated the framed central chip area.

FIG. 12 shows the process of repeating the lamination process for increasing the height of the frame of first compound.

FIG. 13 illustrates a cross section of a substrate strip with a plurality of other exemplary MEMS devices in a thin cavity package, which include thickened portions made of light-sensitive resin according to the invention.

### DETAILED DESCRIPTION OF THE PREFERRED EMBODIMENTS

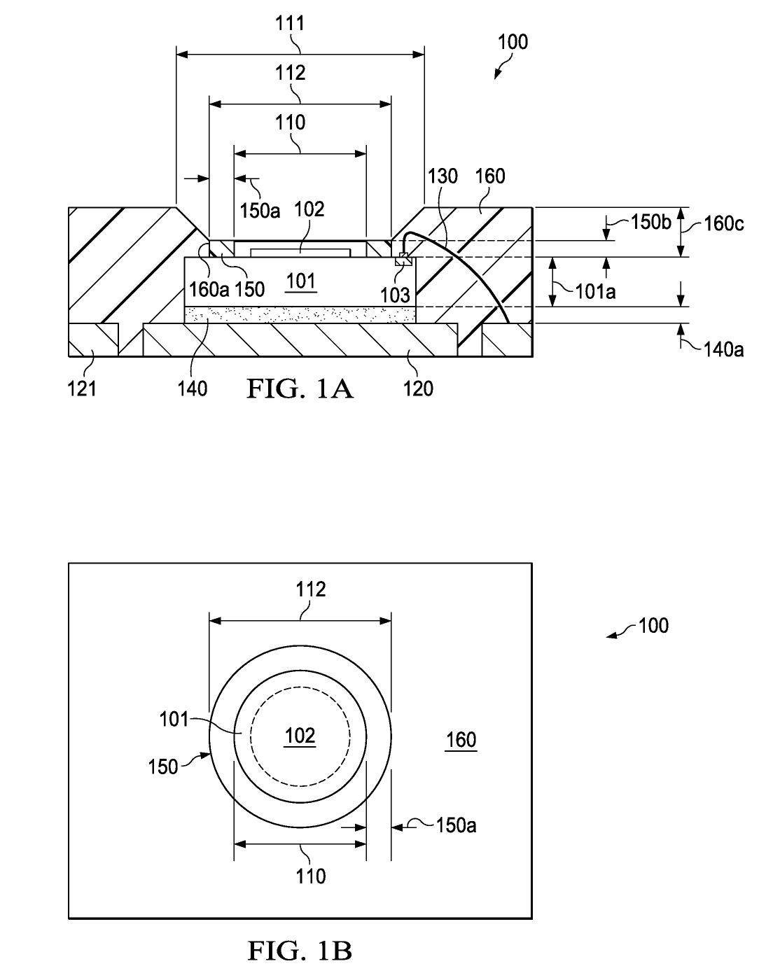

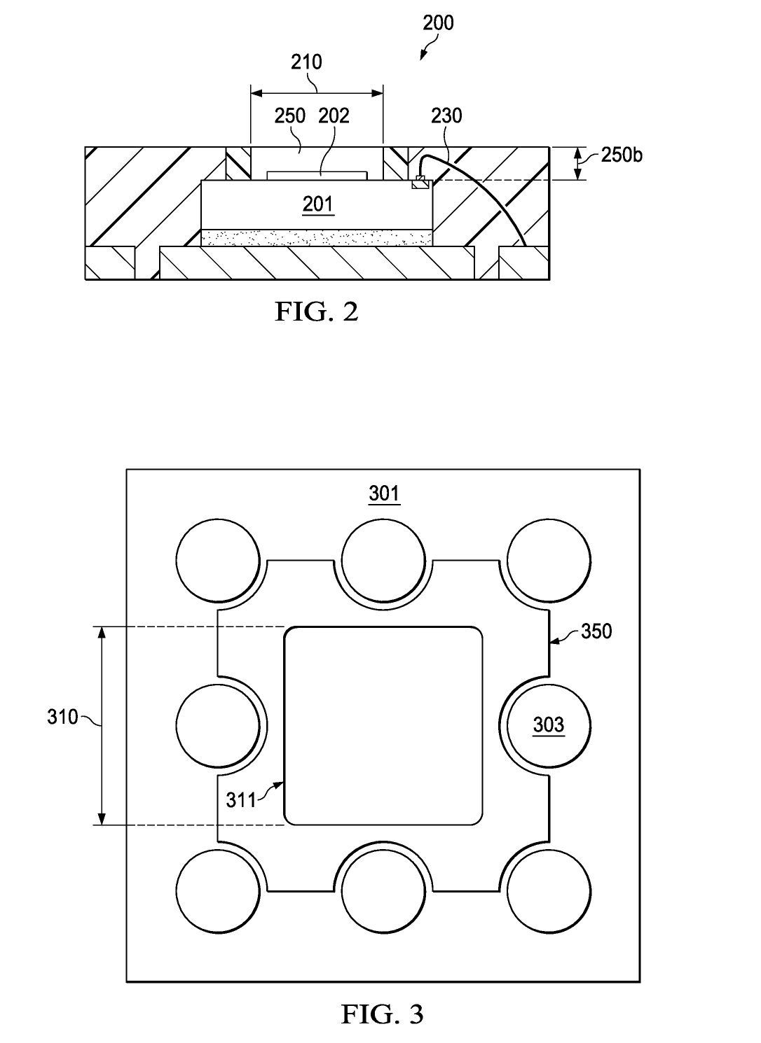

FIGS. 1A and 1B illustrates an exemplary embodiment of the invention, a packaged device generally designated 100, which includes a semiconductor chip 101 with an embedded or attached micro-electrical-mechanical systems (MEMS) device 102 exposed to the ambient by an opening of the package. The MEMS may have any shape, but for simplicity is shown in FIG. 1B to have a circular area. As FIG. 1B illustrates, the opening of the exemplary embodiment has a circular perimeter, and the diameter of the opening is designated 110. In other embodiments, the opening for the MEMS may have a rectangular or a square perimeter, or a perimeter of any other suitable polygon or outline. The exemplary embodiment depicted in FIG. 1A further has a package, which includes in inverted cone of diameter 111 as a wide and smooth onset of the opening. Other embodiments, such as depicted in FIG. 2, have openings with straight walls.

Exemplary packaged device 100 of FIGS. 1A and 1B includes a substrate with a chip attachment pad 120 surrounded by a plurality of metal contacts 121 in the shape of leads. As examples, the substrate may be a multi-metal-layer laminate, or a metallic leadframe. The exemplary leadframe design of FIG. 1A is generally suitable for Quad Flat No-Lead (QFN) and Small Outline No-Lead (SON) type modules; in other devices, the leadframe may include other types of configurations. The preferred base metal of the leadframe includes copper or a copper alloy; alternative metals include aluminum, iron-nickel alloys, and Kovar. Preferred thickness of the leadframe base metal for the exemplary embodiment shown in FIG. 1A is in the range from 0.2 mm to 0.3 mm, other embodiments, however, may use thicker or thinner leadframe metal.

From the standpoint of low cost and batch processing of ledadframes, it is preferred to start with sheet metal and fabricate the leadframe as a strip by stamping or etching. As a consequence of the fact that the starting material is a sheet metal, the leadframe parts are originally in a common plane. When a stamping technique is employed, it can be used both to offset the leads from the original plane and to enlarge the lead areas by coining. It is further practical to flood-plate certain parts of the stamped leadframe with one or more layers of metal in order to achieve certain advantages. For example, the plated metals may promote solder adhesion to those leadframe portions remaining outside a package to be used for connection to externals parts. A preferred metallurgy includes a layer of nickel followed by a layer of palladium, followed by an outermost layer of gold. On the other hand, it may be helpful to spot plate certain leadframe areas; as an example, it is preferred to spot plate certain surfaces of leads 121 for improving stich bonds of copper or gold wires 130.

As stated, other devices use rigid multi-level substrates laminated from a plurality of insulating and conductive layers.

Semiconductor chip 101 of FIG. 1A may have an exemplary lateral dimension of about 1.5 mm; the first height 101a of chip 101 is preferably about 100 μm, yet other devices use thicker (e.g., 650 μm) or thinner chips. First height 101a is correlated with a first tolerance, for instance ±10 μm. In manufacturing operations where 5σ accuracies are practiced, the σ correlated with the exemplary first tolerance is σ₁=2 μm. As FIG. 1A shows, the chip surface includes a central area with a diameter approximately the same as diameter 110 of the package opening. Incorporated in the central area is MEMS device 102. Surrounding the central area are peripheral areas, which contain integrated circuits and terminals; an example of a terminals is shown in FIG. 1A as bonding pad 103.

The chip side opposite the chip surface is attached to substrate pad 120 by an adhesive layer 140. The height 140a of layer 140 is herein referred to as third height and is preferably between about 20 and 30 μm. Third height 140a is correlated with a third tolerance, for instance ±15 μm. In manufacturing operations where 5σ accuracies are practiced, the σ correlated with the exemplary third tolerance is α₃=3 μm. Adhesive layer 140 is preferably made of a polymeric compound, formulated with an epoxy or polyimide resin, and frequently filled with silver particles. These materials are soft and often semi-viscous at time of usage, and after application can be hardened by polymerization (curing) at elevated temperatures. Such adhesive attach materials are sometimes referred to as B-stage polymeric compounds.

FIG. 1A further shows that chip terminals 103 are connected by bonding wires 130 to substrate contacts 121. The exemplary device of FIG. 1A uses bonding wires with squashed balls attached to chip terminals 103. The wire spans between terminals 103 and contacts 121 may require some arching of the wires; the height of these arches (>50 μm for many devices) is a contributing factor for the height of the package material necessary to protect the wire spans. Consequently, the height 160c of the package from the surface of chip 101 to the top of the package is partially determined by the height of the bonding wire arch.

As FIG. 1A illustrates, device 100 is embedded in a package. The package includes a portion 150 made of a light-sensitive first compound and another portion 160 made of an opaque second compound. The package has an opening of diameter 110, which leaves the central area of chip 101, including the MEMS device 102, un-encapsulated and exposed to ambient.

The second compound encapsulates the substrate (with the exception of parts used for connecting to external parts), the wire connections, and the chip peripheral areas including the terminals. Furthermore, the second compound extends from the chip peripheral areas towards the chip central area to form sidewalls 160a around the central area. For instance, for some devices the distance of sidewall 160a from the nearest ball bond is preferably more than 270 μm. The diameter 112 of the opening defined by the sidewalls is greater than the diameter 110 of the opening determined by the first compound.

FIG. 1A shows that the first compound continues from sidewall 160a inwards toward the chip center as a frame 150 around the un-encapsulated central area. For some MEMS devices, it is preferred that the first compound keeps a distance of more than 75 μm from the MEMS device. Frame 150 has a second height 150b; for example, second height 150b may be about 50 μm. In exemplary FIG. 1A, the frame continues at height 150b about equal to the height of the second compound sidewall 160a. In other devices, however, height 150b may be different from the height of sidewall 160a. On either side of the opening, the frame has a width 150a, implied by the difference between diameter 112 and diameter 110. As an example, width 150a may be about 40 μm. Second height 150b is correlated with a second tolerance; see below how this tolerance is correlated with the mold clamp tolerance to obtain an exemplary value of ±35 μm. In manufacturing operations where 5σ accuracies are practiced, the σ correlated with the exemplary second tolerance is σ₂=7 μm.

The first polymeric compound is selected from a group including epoxy-based and polyimide-based resins, which are light-sensitive and stay soft during the temperatures of assembly and packaging processes and thereafter harden by polymerization at elevated temperatures. A polymeric compound with suitable thermoplasticity characteristics is commercially available as chemical DF835P produced by the Hitachi Corporation, Japan; as an example, the material is available as sheets with a film thickness of 50 μm.

The second polymeric compound is an epoxy-based molding resin filled with inorganic fillers, which is semi-viscous during the molding process and thereafter hardens by polymerization.

Another embodiment 200 is illustrated in FIG. 2. First polymeric compound 250 is shown to have a height 250b about twice as high as height 150b in FIG. 1A; for instance, height 250b may be about 100 μm. While this height may be sufficient to accommodate the arches of bonding wires 230, it still allows a flat package surface and a thinner overall package height for device 200 than the embodiment illustrated in FIG. 1A. On the other hand, the package of device 200 maintains a circular configuration for opening 210 around the center of chip 201 with the MEMS device 202, similar to FIG. 1B.

FIG. 3 illustrates another embodiment of a package for a MEMS device. The package is transparent for demonstration purposes and shows the square-shaped semiconductor chip 301 (lateral dimensions 1.5 mm by 1.5 mm). On the chip is the photosensitive resin 350, which defines a square-shaped opening 311 with a side length 310 of about 0.55 mm for exposing the MEMS device (not shown in FIG. 3). The photomasks used for contouring the resin (methodology is described below) allow the fabrication of relatively complicated configurations. The embodiment of FIG. 3 shows outlines of the light-sensitive resin for accommodating a plurality of terminals pads 303 in close proximity to the opening 311. Pads 303 may be used for ball bonding or solder balls.

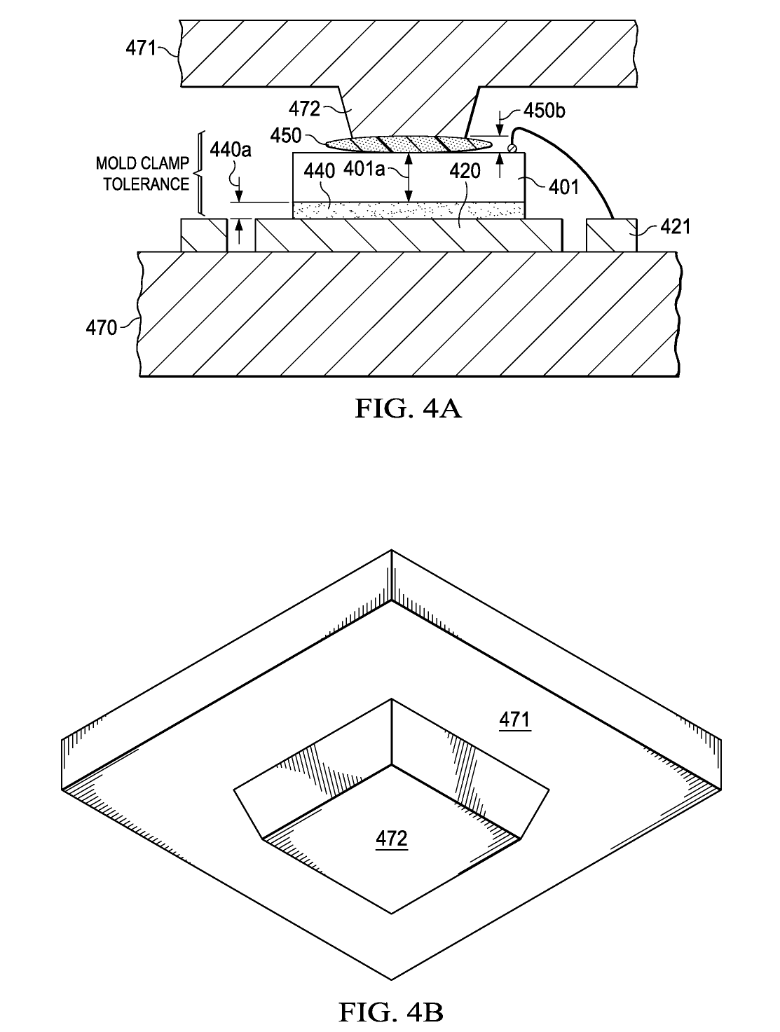

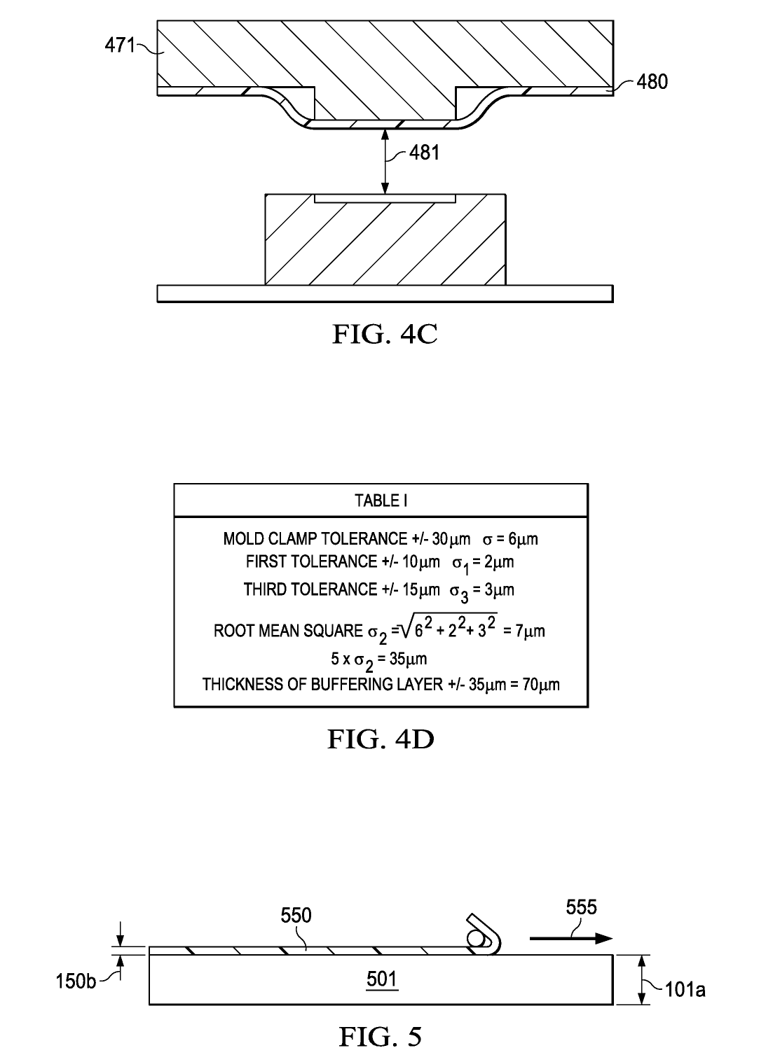

FIGS. 4A to 4D discuss the concept of determining the thickness of the light-sensitive first polymeric compound. In FIG. 4A, semiconductor chip 401 of height 401a is attached by adhesive layer 440 of height 440a to rigid substrate pad 420 with terminals wire-bonded to leads 421. Substrate 420 is placed on the flat bottom portion 470 of a molding apparatus. The stiff, but flippable top portion of the molding apparatus is cover 471, which has a plurality of protrusions 472. Each protrusion is designed to come to rest on a layer 450 of soft polymeric compound positioned on the surface of the chip of a respective device. In the example of FIG. 4B, protrusion 472 has the shape of a truncated pyramid. It determines the shape of the opening in the device package to expose the center of the assembled chip with the MEMS device. In other embodiments, the protrusions may be shaped as a truncated cone or any other polyhedral or stereometric body. Soft Layer 450 acts as a spacer or buffer between the rigid assembled chip on the rigid mold bottom 470 and the rigid mold cover 471, compensating for and equalizing any process margin. Layer 450 has the height 450b, herein referred to as second height, coupled with a second tolerance.

Following the earlier practice of FIG. 1A, chip height 401a is called the first height, which is correlated with a first tolerance. In Table I, the first tolerance has an exemplary value of ±10 μm. In manufacturing operations where 5σ accuracies are practiced, the σ correlated with the exemplary first tolerance is σ₁=2 μm. The height 440a of the adhesive layer 440 for chip attachment is called the third height, which is correlated with a third tolerance. In Table I, the third tolerance has an exemplary value of ±15 μm. In manufacturing operations where 5σ accuracies are practiced, the σ correlated with the exemplary first tolerance is σ₃=3 μm.

The process of closing the mold chamber for filling the chamber with molding compounds involves the clamping of the mold cover 471 over the mold cavity with the assembled chip 401. As indicated in FIG. 4A, the clamping operation is correlated with a tolerance, which includes the first and third tolerances as well as the second tolerance of the height of soft layer 450. An example of a numerical value (±30 μm) is given in Table I of FIG. 4D. In manufacturing operations where 5σ accuracies are practiced, the σ correlated with the mold clamp tolerance is σ=6 μm.

From the standpoint of smooth operation, it is reasonable to determine the thickness 450b of compensating layer 450 so that it takes the value of the mold clamp tolerance into account, together with the tolerances of chip thickness and attach thickness. FIG. 4D indicates how the thickness of the buffering layer 450 with its correlated σ₂ is calculated. The root mean square σ₂ is the square root of the sum of the square σ's of the entities discussed above. FIG. 4D gives as an exemplary value σ₂=7 μm. In manufacturing operations where 5σ accuracies are practiced, the tolerance correlated with σ₂ is ±35 μm, resulting in a thickness of 70 μm for the buffering layer 450b.

FIG. 4C shows the practice that in some molding apparatus a release film 480 is used, which is placed over the surface of cover 471 during the molding process. The thickness of release film 480 can typically absorb a tolerance of ±10 μm. Film 480 may thus contribute to the adjusting function of buffer layer 450b, but is insufficient to take on its full tolerance function, symbolized in FIG. 4C by distance 481.

Another embodiment of the invention is a method for fabricating a packaged MEMS device with a photosensitive resin. FIGS. 5 to 14 illustrate certain processes in the fabrication flow for semiconductor cavity packages with MEMS devices. The flow will illustrates why it is a technical advantage to exploit the flexibility of a photosensitive characteristic of the resin material used to form the buffer and spacer layer as portion of the package. The process flow starts in FIG. 5 by providing a semiconductor wafer 501 of a first height 101a. The wafer has a plurality of chip sites, with each site including a central area with a MEMS device (not shown in FIG. 5) and peripheral areas with integrated circuits and terminals.

FIG. 5 shows that in the next process a plastic film 550 of a soft and light-sensitive first polymerizable compound is laminated over the surface of the wafer; the direction of lamination is indicated by arrow 555. The film has a second height 150b coupled with a second tolerance. For example, second height 150b may be about 50 μm. The light-sensitive first polymeric compound is sensitive to ultraviolet (UV) irradiation; the compound stays soft during the temperatures of assembly and packaging processes and thereafter hardens by polymerization at elevated temperatures. A polymeric compound with suitable thermoplasticity characteristics is, for instance, commercially available as chemical DF835P produced by the Hitachi Corporation, Japan.

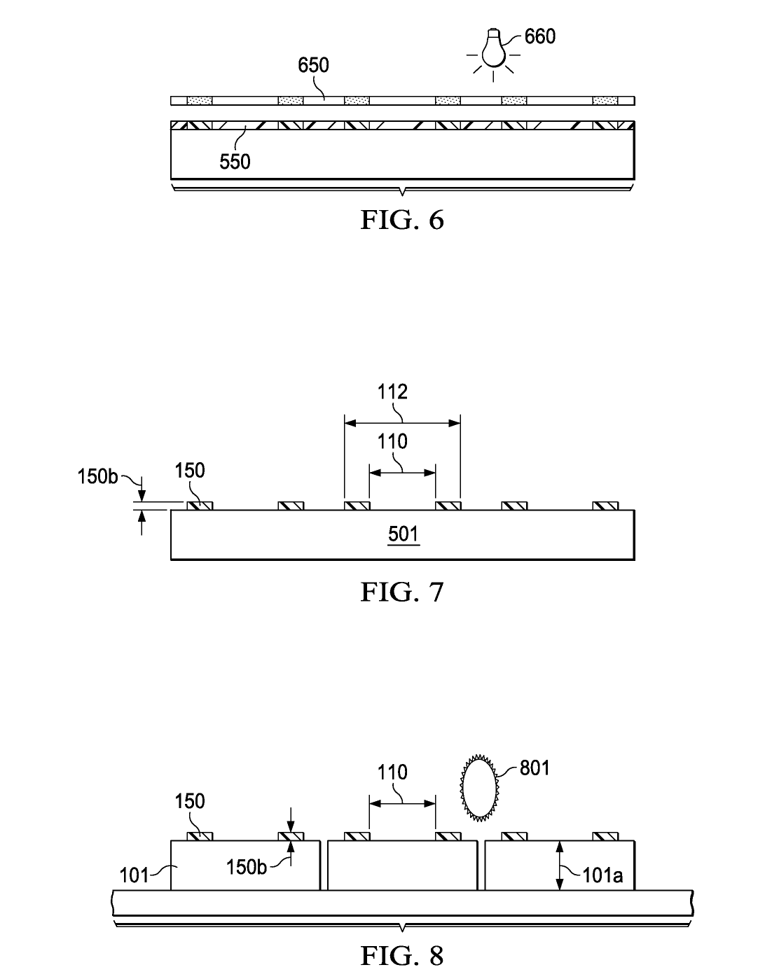

It is a technical advantage that film 550 can be patterned at short notice in any customized pattern by simply applying a custom-made and low cost photomask followed by suitable processes for light-exposing, developing, and etching. The photomask is designed to anticipate the frame structures for a plurality of devices, where the frames are to become a portion of the package openings of plastic-packaged chips with MEMS devices. The photomask has patterns defining the outlines and widths for frames around the central area of each chip site. The degree of freedom and flexibility offered by the light-sensitive polymeric fail is helpful in a market place, where quick response to customer requests is at a premium. FIG. 6 depicts the processes of aligning a photomask 650 over film 550 and then exposing film 550 to UV radiation 660 through photomask 650. The exposed film 650 is then developed.

FIG. 7 illustrates the process of etching the developed film 550. The etching process retains the un-etched film portions 150 as the frames of soft first compound and second height 150b around the central area of each chip site. The inner frame diameter 110 for the package opening and the outer frame diameter 112 of the frame are thus anticipated.

FIG. 8 depicts the dicing the wafer 501 by a saw 801 in order to singulate a plurality of discrete semiconductor chips 101 of first height 101a, each chip including a central chip area of diameter 110 with a MEMS device (not shown in FIG. 8), surrounded by a frame 150 of soft first compound and second height 150b, and a peripheral chip area with terminals.

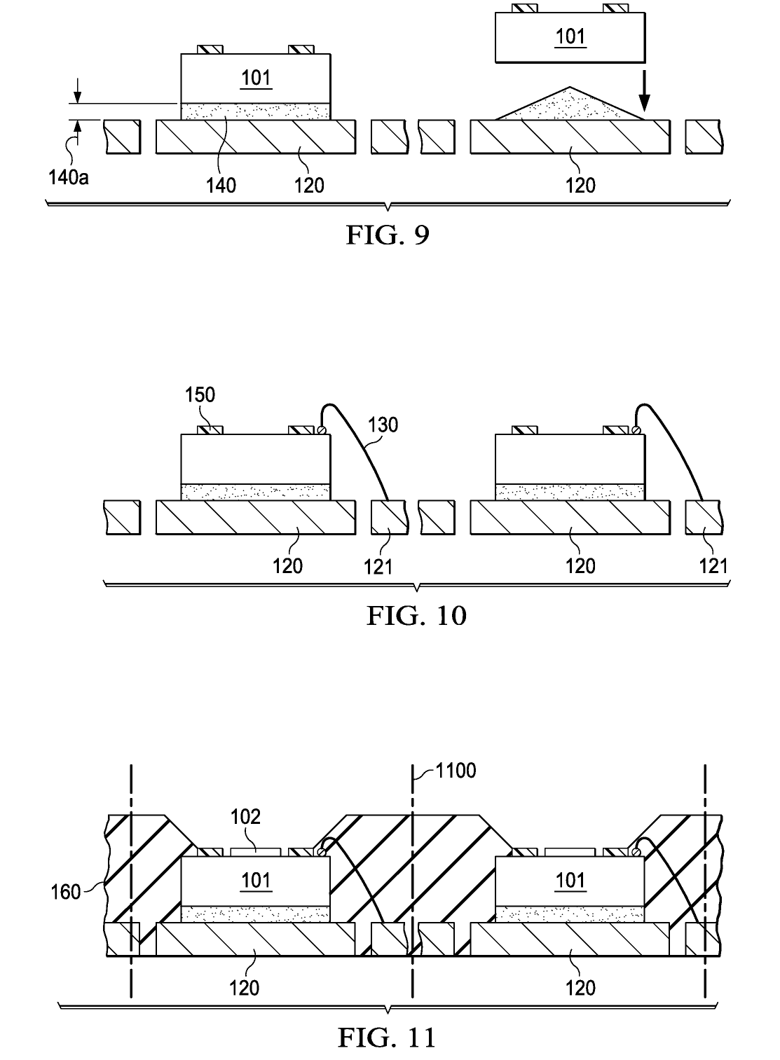

In FIG. 9, a plurality of semiconductor chips 101 are attached on the pads 120 of a rigid substrate strip 122 (such as leadframe strip or laminate substrate strip) using adhesive polymeric compound spread as layers 140 of a third height 140a coupled with a third tolerance. In FIG. 10, the chip terminals are connected by bonding wires 130 to adjacent substrate metal contacts 121 of the substrate strip 122.

In the next process, a strip with the attached chips is placed on the rigid bottom of a mold having a rigid cover 471 with solid protrusions 472 configured to fill the space over the framed central area of each chip attached to the strip. Next, the mold is closed by clamping the mold cover 471 until a respective protrusion 472 touches the frame of soft first compound 150 surrounding the central area of each chip. The process of clamping is coupled with a tolerance (as discussed in FIGS. 4A and 4D).

After closing the mold, the temperature is raised and semi-viscous polymeric compound 160 is pressured into the mold chamber to encapsulate the substrate surface, wire connections, and chip peripheries contiguous with the frames using an opaque second polymerizable compound (such as an epoxy-based polymerizable compound filled with inorganic particles). In this process, each framed central chip area covered by a protrusion is left un-encapsulated.

After the encapsulation process, the temperature is left elevated to polymerize and harden the first and second compounds before opening the mold cover. FIG. 11 illustrates the substrate strip after opening the mold, showing the overmolded strip of packaged devices with central openings containing MEMS devices 102. Phantom lines 1100 indicate the cuts to be made through strip 122 by saws in order to singulate discrete devices with central openings containing MEMS devices 102. An exemplary device is depicted in FIG. 1A.

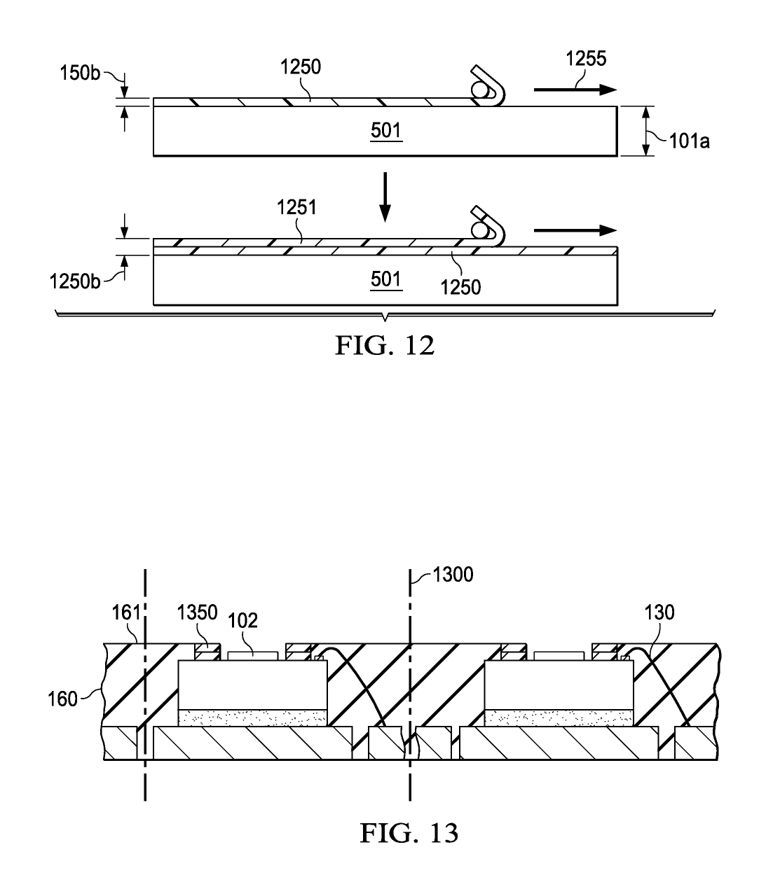

FIG. 12 illustrates the process of including one or more repetitions of the process of laminating so that one or more plastic films of second height 150b are placed on the first film, thereby doubling or multiplying the height of the film stack. The process flow starts in FIG. 12 by providing a semiconductor wafer 501 of a first height 101a. The wafer has a plurality of chip sites, with each site including a central area with a MEMS device (not shown in FIG. 12) and peripheral areas with integrated circuits and terminals.

FIG. 12 shows that in the next process a first plastic film 1250 of a soft and light-sensitive first polymerizable compound is laminated in the direction 1255 over the surface of the wafer. The film has a second height 150b coupled with a second tolerance. For example, second height 150b may be about 50 μm. The light-sensitive first polymeric compound is sensitive to ultraviolet (UV) irradiation; the compound stays soft during the temperatures of assembly and packaging processes and thereafter hardens by polymerization at elevated temperatures. Then, a second plastic film 1251 of film height 150b is laminated in the direction 1255 over the first plastic film 1250, doubling the film height. For some devices, the process of laminating may be repeated several times. The final height of the film stack is designated 1250b. Height 1250b is selected to accommodate the arches of the spans of bonding wires 130 (see FIG. 13) needed for reliable wire bonding.

After completing the process of laminating a film stack of light-sensitive first polymerizable compound, the subsequent processes of aligning a photomask, illuminating, developing and etching the film stack, dicing the wafer into chips, attaching a plurality of chips to a substrate, and encapsulating the assembly in an opaque second polymerizable compound 160, follow the order described in FIGS. 5 to 11 in analogous fashion. In addition, the hardening of the first and second polymeric compounds at elevated temperature is analogous. However, since the height 1250b of the film stack is sufficient to accommodate the height of the wire span arches needed for wire bonding, the flippable cover of the mold does not need protrusions as described in FIGS. 4A and 4B; instead, the flat cover can rest directly on the increased height 1250b of the film stack of light-sensitive first polymeric compound.

Consequently, the substrate strip illustrated in FIG. 13, after opening the mold, shows a flat top surface 161 of the overmolded strip of packaged devices, which is coplanar with the surface of hardened polymeric stack 1350. As a result, the package height can be reduced compared to the package height of the device in FIG. 1A. Again, each device exhibits a central opening containing a MEMS device 102 framed by the hardened stack 1350. Phantom lines 1300 indicate the cuts to be made through strip 122 by saws in order to singulate discrete devices with central openings containing MEMS devices 102.

The fabrication method described above is applicable to a wide variety of MEMS devices positioned on, or embedded in semiconductor chips. The list of MEMS devices may include, but is not limited to, infrared temperature sensors, ambient light sensors, infrared proximity sensors, depth sensors, Hall effect sensors, radio frequency varactors, infrared thermopile imagers, fluxgate magnetometers, humidity sensors, pressure sensors, and biosensors.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing.

As another example, the invention applies to MEMS having parts moving mechanically under the influence of an energy flow (acoustic, thermal, or optical), a temperature or voltage difference, or an external force or torque. Certain MEMS with a membrane, plate or beam can be used as a pressure sensor (for instance microphone and speaker), inertial sensor (for instance accelerometer), or capacitive sensor (for instance strain gauge and RF switch); other MEMS operate as movement sensors for displacement or tilt; bimetal membranes work as temperature sensors.

It is therefore intended that the appended claims encompass any such modifications or embodiment.

I claim:

1. A packaged micro-electro-mechanical system (MEMS) device comprising:
a rigid substrate having a chip pad surrounded by a plurality of metal contacts;
a semiconductor chip of a first height, the chip surface including a central area with a MEMS device and peripheral areas with terminals, the chip side opposite the surface attached to the substrate pad by an adhesive layer of a third height, the chip terminals wire-connected to the substrate contacts; and
a package including a light-sensitive first and an opaque second polymerized compound, the second compound encapsulating the substrate, the wire connections, and the chip peripheral areas including the terminals, and further forming a sidewall around the un-encapsulated central area; and the first compound continuing from the sidewall as a frame around the un-encapsulated central area, the frame having a second height and a width.

2. The device of claim 1 wherein the first polymeric compound is selected from a group including epoxy-based and polyimide-based resins, which are light-sensitive and stay soft during the temperatures of assembly and packaging processes and thereafter harden by polymerization at elevated temperatures.

3. The device of claim 2 wherein the second polymeric compound is an epoxy-based molding resin filled with inorganic fillers, which is semi-viscous during the molding process and thereafter hardens by polymerization.

4. A method for fabricating a packaged micro-electro-mechanical system (MEMS) device comprising:
providing a semiconductor wafer of a first height, the wafer having a plurality of chip sites, each site including a central area with a MEMS device and peripheral areas with integrated circuits and terminals;
laminating a plastic film of a soft and light-sensitive first polymerizable compound over the surface of the wafer, the soft film having a second height;
aligning a photomask over the film, the photomask having patterns defining the outlines and widths for frames around the central area of each chip site;
illuminating, developing and etching the film, retaining un-etched film portions as frames of soft first compound and second height around the central area of each chip site;
dicing the wafer to singulate a plurality of discrete semiconductor chips of first height, each chip including a central area surrounded by a frame of soft first compound and second height, and peripheral areas with terminals;
attaching a plurality of semiconductor chips on the pads of a rigid substrate strip using adhesive layers of a third height, and wire-bonding the chip terminals to adjacent substrate metal contacts;
placing the strip with the attached chips in a mold having a rigid cover with solid protrusions configured to fill the space over the framed central area of each chip;
clamping the mold cover until a respective protrusion touches the frame of soft first compound surrounding the central area of each chip;
encapsulating the substrate surface, wire connections, and chip peripheries contiguous with the frames using an opaque second polymerizable compound, leaving un-encapsulated each framed central area covered by a protrusion; and
raising the temperature to polymerize and harden the first and second compounds and then opening the mold cover, thereby exposing the strip of packaged devices with central openings containing MEMS devices.

5. The method of claim 4 further including the process of sawing the substrate strip to singulate discrete devices of encapsulated chips having MEMS devices in the package opening.

6. The method of claim 4 wherein the first height is correlated with a first tolerance, the third height is correlated with a third tolerance, the process of clamping is correlated with a fourth tolerance, and the second height is selected so that its correlated second tolerance permits at least a 5σ operation of the encapsulating process.

7. The method of claim 6 further including one or more repetitions of the process of laminating so that one or more soft plastic films are placed on the first film and their combined second heights and correlated tolerances permit at least a 5σ operation of the encapsulating process.

8. The method of claim 4 wherein the first polymerizable compound is selected from a group including epoxy-based and polyimide-based resins, which are light-sensitive and stay soft during the temperatures of assembly and packaging processes and thereafter harden by polymerization at elevated temperatures.

9. The method of claim 8 wherein the second polymerizable compound is an epoxy-based thermoset molding resin filled with inorganic fillers, which is semi-viscous during the molding process and thereafter hardens by polymerization.
